(19) United States
(12) Patent Application Publication
(10) Pub. No.: US 2009/0327836 A1
(43) Pub. Date: Dec. 31, 2009

(54) Decoding method for convolution code and decoding device

(75) Inventor: Masakazu Shimizu, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/457,036

(22) Filed: May 29, 2009

(30) Foreign Application Priority Data
Jun. 27, 2008 (JP) 2008-168403

(51) Int. Cl. H03M 13/00; G06F 11/08

(52) U.S. Cl. 714/758; 714/E11.03; 714/752

(57) ABSTRACT

A decoding method performs turbo decoding on data that includes a first value before transmission and that includes a second value after received, the second value changed from the first value due to the influence of a transmission path. The decoding method includes performing the turbo decoding on the data to obtain a log-likelihood ratio for the second value, converting the second value to a third value that is obtained by correcting the second value to become closer to the first value when a decoded result from the turbo decoding on the data includes an error and when an absolute value of the log-likelihood ratio is equal to or greater than a predetermined threshold value; and performing the turbo decoding on the data including the third value to obtain a decoded result of the data.

### INCORPORATION BY REFERENCE

This application is based upon and claims the benefit of priority from Japanese Patent Application No. 2008-168403 which was filed on Jun. 27, 2008, the disclosure of which is incorporated herein in its entirety by reference.

### BACKGROUND OF THE INVENTION

1. Field of the Invention

The present invention relates to a decoding device, a decoding method, and a program that improve error correction capability of a convolutional code such as in turbo decoding or Viterbi decoding.

2. Description of Related Art

Digital communication systems use error correcting codes that correct errors caused in a transmission path. Particularly in mobile communication systems, the error correcting code requires high error correction capability since a great fluctuation in radio field intensity due to an influence of phasing easily causes an error. A turbo code, which is one example of the error correcting codes, is attracting attention as a code having error correction capability close to Shannon limit, and is used in, for example, third generation mobile communication systems such as W-CDMA (Wideband Code Division Multiple Access) and CDMA-2000.

The Viterbi decoding is a decoding method for the convolutional codes, and is known as one of the most general error correcting methods. The Viterbi decoding is a maximum likelihood decoding method for obtaining a decoded result by tracing back the most likely state transition. Error detection methods such as CRC (Cyclic Redundancy Check) are used to decide whether the decoded result is correct, and a retransmission of data is requested in the case of an error.

A decoding device that improves the error correction capability of these convolutional codes has been conventionally proposed. FIG. 11 is a block diagram showing a decoding device of a related art (for example, see Patent Document 1). As shown in FIG. 11, a decoding device 100 includes an input data memory 112, a synthesizer 113, a decoder 114, a decoded data memory 115, a hard decider 116, an error detector 117, a controller 119, and a signal-to-noise ratio estimator 122.

The input data memory 112 stores data from a receiver (not shown). The synthesizer 113 synthesizes data from the input data memory 112 and data from the signal-to-noise ratio estimator 122. The decoder 114 performs turbo decoding. The decoded data memory 115 saves a decoded data reliability (Log-Likelihood Ratio (LLR)). The hard decider 116 obtains a hard decision result as a result of a hard decision on a decoded result based on the LLR. The error detector 117 performs error detection from the hard decision result using the CRC. In response to a detection of an error of the decoded data by the error detector 117, the controller 119 takes control of causing the error detector 117, the decoder 114 and the synthesizer 113 to start (restart). The signal-to-noise ratio estimator 122 includes a root-mean-square circuit 122a and a lookup table 122b. The root-mean-square circuit 122a estimates the signal-to-noise ratio of a block in processing on the basis of soft output data (LLR) from the decoded data memory 115. The lookup table 122b stores data showing the correspondence relation between the signal-to-noise ratio and IER. The IER stands for “Input to Extrinsic Data Ratio,” and is the proportion of input data for extrinsic likelihood information (extrinsic information).

When the IER outputted from the lookup table 122b is low, i.e., when the reliability of received data and coded data is high, the synthesizer 113 amplifies the received data and coded data with a small gain so as to estimate the decoded result based on the received data and the coded data mainly. On the other hand, when the IER outputted from the lookup table 122b is high, i.e., when the reliability of the received data and the coded data is low, the received data and the coded data are amplified with a large gain so as to estimate the decoded result from a calculation result of a decoder mainly.

FIG. 12 is a block diagram showing a decoding device according to another related art (for example, see Patent Document 2). As shown in FIG. 12, a decoding device 200 includes an input data memory 212, a synthesizer 213, a decoder 214, a decoded data memory 215, a hard decider 216, an error detector 217, a controller 219, a code mapper 224, and an equalizer 225.

The input data memory 212 stores data from a receiver (not shown). The synthesizer 213 synthesizes data from the input data memory 212 and data from the equalizer 225. The decoder 214 performs turbo decoding. The decoded data memory 215 saves the decoded data reliability (LLR). The hard decider 216 obtains a hard decision result of a hard decision on a decoded result based on the LLR. The error detector 217 performs error detection of the hard decision result by using the CRC. The controller 219 controls the error detector 217, the decoder 214, and the synthesizer 213.

The hard decider 216 obtains the hard decision result of the decoded result from likelihood information of both of a system bit and a parity bit stored in the decoded data memory 215. The code mapper 224 performs code re-mapping by the hard decision result. The equalizer 225 adjusts the next input data by feeding back the hard decision result to the input data.

[Patent Document 1] Japanese Patent Application Laid Open No. 2001-230681

[Patent Document 2] Japanese Patent Application Laid Open No. 2003-535493

### SUMMARY

However, while the decoding device described in Patent Document 1 estimates the signal-to-noise ratio of received data to be decoded, on the basis of the LLR, it is extremely difficult to accurately estimate the signal-to-noise ratio. In the case of performing an accurate estimation of the signal-to-noise ratio, lookup tables need to be prepared in a finer granularity, and the circuit size of the decoding device increases. On the other hand, when the granularity of the lookup table is made coarse in order to suppress the increase of the circuit size as much as possible, the signal-to-noise ratio cannot be estimated with appropriate accuracy. In other words, the decoding device described in Patent Document 1 corrects data stored in the input data memory 112 based on the estimation result of the signal-to-noise ratio. However, the decoding device cannot appropriately correct the data stored in the input data memory 112 if the accuracy of the estimation of the signal-to-noise ratio is low. As a result, even if the data after correction is decoded, the decoded result may again have error.

The decoding device described in Patent Document 2 may obtain an incorrect hard decision result which is the result of the hard decision of the decoded result. Thus, even when the received data which is stored in the input data memory 212 is weighted using the hard decision of the decoded result, it is unclear whether the data to be decoded is weighted correctly. In other words, in some cases, the decoding device described in Patent Document 2 may fail to perform an appropriate correction on the data to be decoded. Thus, even if the data after correction is decoded again by the decoder 214, the decoded result may again have error. In summary, the decoding device using the technique of the related art has a problem to be solved that: the received data may fail to be corrected appropriately in some cases; an attempt to appropriately correct the data to be decoded and obtain a decoded result without error requires a significant increase in circuit size, while an attempt to reduce the circuit size causes deterioration in the accuracy of correction for the data to be decoded and makes it difficult to obtain the correct decoded result.

A decoding method according to an exemplary aspect of the present invention is a decoding method of performing turbo decoding on data that includes a first value before transmission and that includes a second value after reception, the second value changed from the first value due to the influence of a transmission path, the decoding method characterized by comprising the steps of: performing the turbo decoding on the data to obtain a log-likelihood ratio for the second value; converting the second value to a third value that is obtained by correcting the second value to become closer to the first value when a decoded result from the turbo decoding on the data has error, and when an absolute value of the log-likelihood ratio is equal to or greater than a predetermined threshold value; and performing the turbo decoding on the data including the third value to obtain a decoded result of the data.

A decoding device according to an exemplary aspect of the present invention comprises: decoder that performs turbo decoding on data that includes a first value before transmission and that includes a second value after reception, the second value changed from the first value due to the influence of a transmission path, and thereby obtains a log-likelihood ratio for the second value; a correction decider that issues an instruction to correct the second value when a decoded result from the turbo decoding has error and when an absolute value of the log-likelihood ratio is equal to or greater than a predetermined threshold value; and a corrector that converts the second value to a third value that is obtained by correcting the second value to become closer to the first value, wherein that the decoder performs the turbo decoding again on the data including the third value.

In the exemplary aspects of the present invention, the log-likelihood ratio obtained by the turbo decoding is compared with the predetermined threshold value. When the absolute value of the log-likelihood ratio is equal to or greater than the predetermined threshold value, it can be estimated that the result of the hard decision using the log-likelihood ratio obtained by the turbo decoding is correct. In this case, the received data corresponding to the log-likelihood ratio is corrected to be closer to a first value that has probably been transmitted. Since it suffices to correct the received data corresponding to the log-likelihood ratio based on a criterion on whether the absolute value of the log-likelihood ratio is greater than the predetermined threshold value, complicated processing such as the estimation of a signal-to-noise ratio described in the technique of the related art does not be needed to be performed. As a result, an increase in circuit size can be suppressed to improve the accuracy of the decoding. Since the correction is performed based on the log-likelihood ratio that is obtained before performing the hard decision, the data to be decoded can be corrected appropriately.

According to the present invention, it is possible to achieve a decoding method that can improve the error correction capability, and to provide a decoding device in which an increase in circuit size is suppressed while the error correction capability is improved.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a view showing an information processing system according to a first exemplary embodiment of the present invention;

FIG. 2 is a view showing data outputted by each block;

FIG. 3 also is a view showing data outputted by each block;

FIG. 4 is a block diagram showing a decoder (decoding device) according to the first exemplary embodiment of the present invention;

FIG. 5 is a view illustrating correction processing performed by a corrector;

FIG. 6 is a view illustrating correction processing performed by a corrector according to a modified example of the first exemplary embodiment of the present invention;

FIG. 7 is a flowchart showing a correction method according to the first exemplary embodiment of the present invention;

FIG. 8 is a view showing the effect of the first exemplary embodiment of the present invention, and is a graph diagram showing the error correction capability;

FIG. 9 is a view showing another effect of the first exemplary embodiment of the present invention, and is a graph diagram showing a reduction effect in the repeated number of times;

FIG. 10 is a view showing a decoding device according to a second exemplary embodiment of the present invention;

FIG. 11 is a block diagram showing a decoding device according to a reference example of the related art; and

FIG. 12 is a block diagram showing a decoding device according to another reference example of the related art.

### DETAILED DESCRIPTION OF THE EXEMPLARY EMBODIMENTS

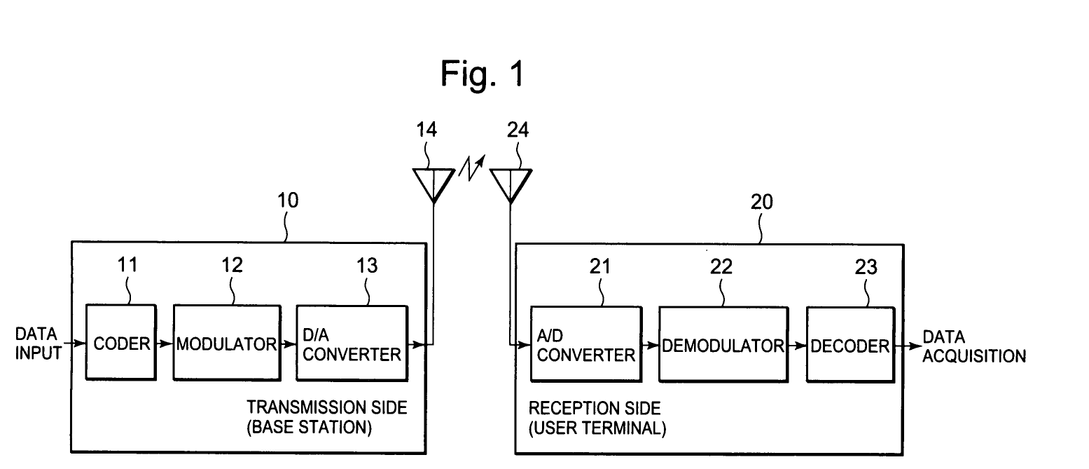

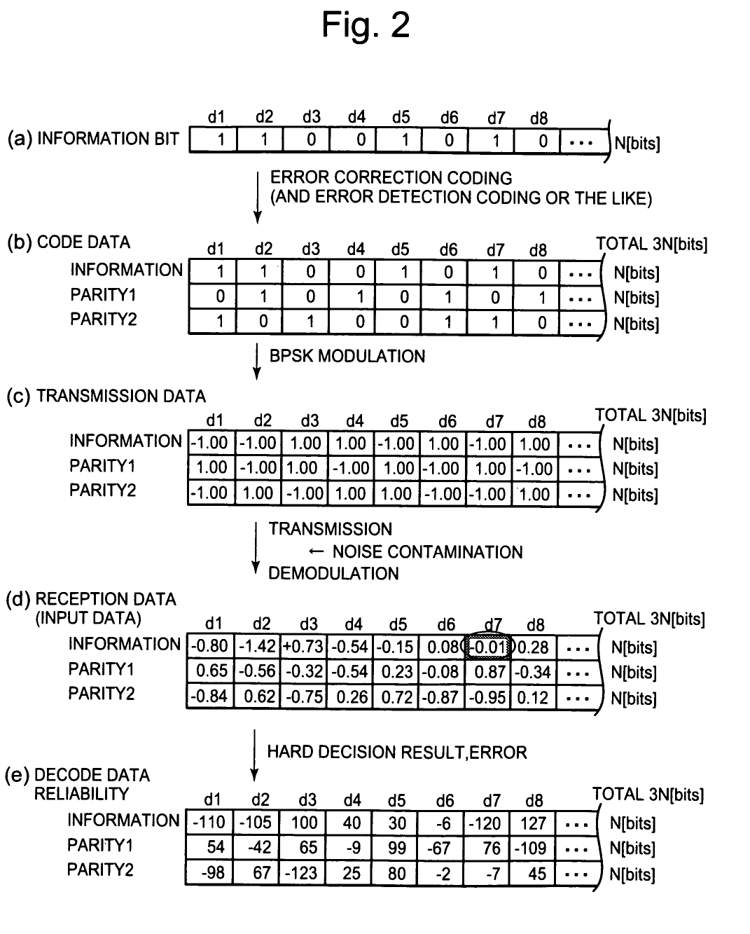

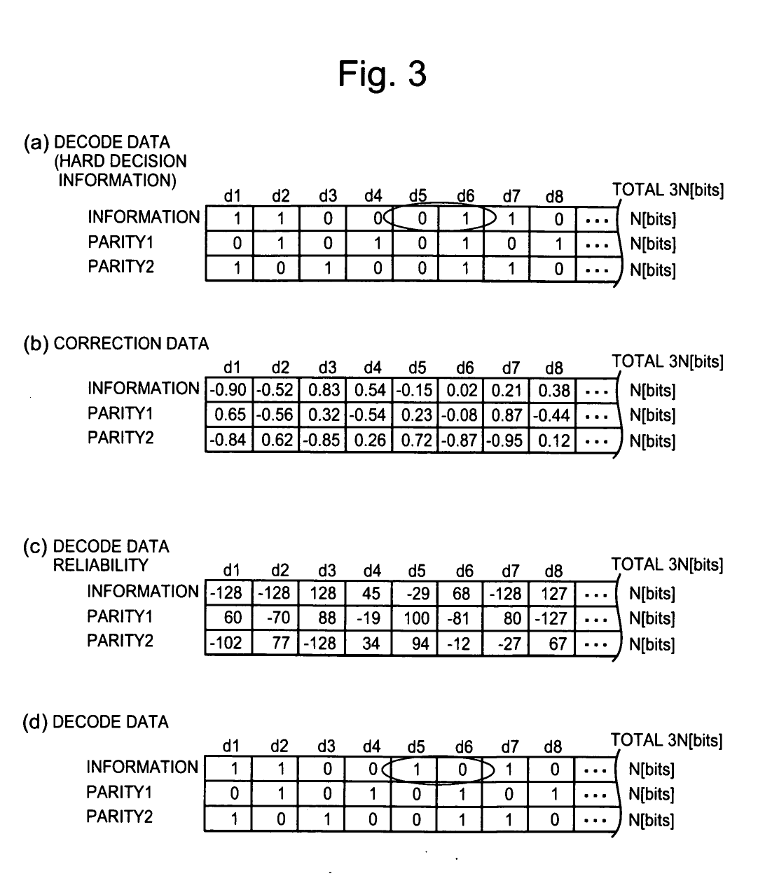

FIG. 1 is a view showing an information communication system according to a first exemplary embodiment of the present invention. FIGS. 2 and 3 are views showing data outputted by each block. As shown in FIG. 1, the transmission side is, for example, a base station 10, and includes a coder 11, a modulator 12, a D/A converter 13, and an antenna 14. For example, in the base station 10, a CPU (not shown) of the base station 10 first inputs data intended to be transmitted to the coder 11 as information bits (FIG. 2A). The coder 11 performs error correction coding (and error detection coding or the like) such as turbo decoding on the inputted information bits (FIG. 2B). As shown in FIG. 2A, the information bits are a bit string consisting of 1 or 0. When the coder 11 performs the turbo decoding of the information bits, if the coding rate is, for example, then coded data which is coded data has a bit number three times that of the information bits 1/3 since parities are added to the information bits. In FIGS. 2 and 3, code data, transmission data, received data, decoded data reliability, and correction data each have a bit number three times that of the information bits and decoded data. The coder 11 outputs code data (FIG. 2B) obtained by the error correction coding, e.g., turbo decoding, of the inputted information bits to the modulator 12. The modulator 12 modulates the inputted code data with a binary phase shift keying (BPSK) system (FIG. 2C), and outputs the transmission data (FIG. 2C) which is data after modulation to the D/A converter 13. The D/A converter 13 converts the transmission data outputted by the modulator 12 from a digital signal to an analog signal. The transmission data converted to the analog signal is transmitted via the antenna 14. As shown in FIG. 2C, when performing the BSPK modulation on the code data, the modulator 12 converts bits “0” of the code data to 1.00 and bits “1” of the code data to −1.00.

The receiving side is, for example, a user terminal 20. The user terminal 20 receives the data transmitted from the antenna 14 of the transmission side 10 via an antenna 24. Note that the data received by the antenna 24 has been influenced by noise during spatial propagation after being outputted from the antenna 14. The data received by the antenna 24 is inputted to an A/D converter 21. The A/D converter 21 converts the inputted data from an analog signal to a digital signal. The A/D converter 21 outputs the digital signal after conversion to a demodulator 22. The demodulator 22 demodulates the data outputted by the A/D converter 21. Data obtained as a result of the demodulation performed by the demodulator 22 is the received data shown in FIG. 2D. Here, the data transmitted from the transmission side is contaminated with noise before being received via a communication path. The noise changes in magnitude along with time. Thus, the noise has an influence also upon the received data (FIG. 2D) obtained as the result of the demodulation performed by the demodulator 22. In the received data shown in FIG. 2D, noise is added to an extent that the sign of data of d7 is inverted. Since the received data obtained by the demodulation performed by the demodulator 22 is contaminated with noise in this manner, a difference exists between the received data and the original transmission data (FIG. 2C) at the point of modulation performed by the modulator 12 on the transmission side. The demodulator 22 outputs the received data obtained by the demodulation to a decoder 23. The decoder 23 performs an error correction decoding on the inputted received data. The decoder 23 performs the error correction decoding on the received data and corrects an error of the received data due to noise. As a result of the error correction decoding, the reliability of the decoded data can be obtained (for example, FIG. 2E of which specific operations will be described later). The decoder 23 of this exemplary embodiment performs turbo decoding on the received data. As a result of performing the turbo decoding, the decoded data (FIG. 3A) is obtained based on the obtained reliability (log-likelihood ratio or LLR), and a processing circuit such as a CPU performs a predetermined processing in a subsequent stage using the decoded data.

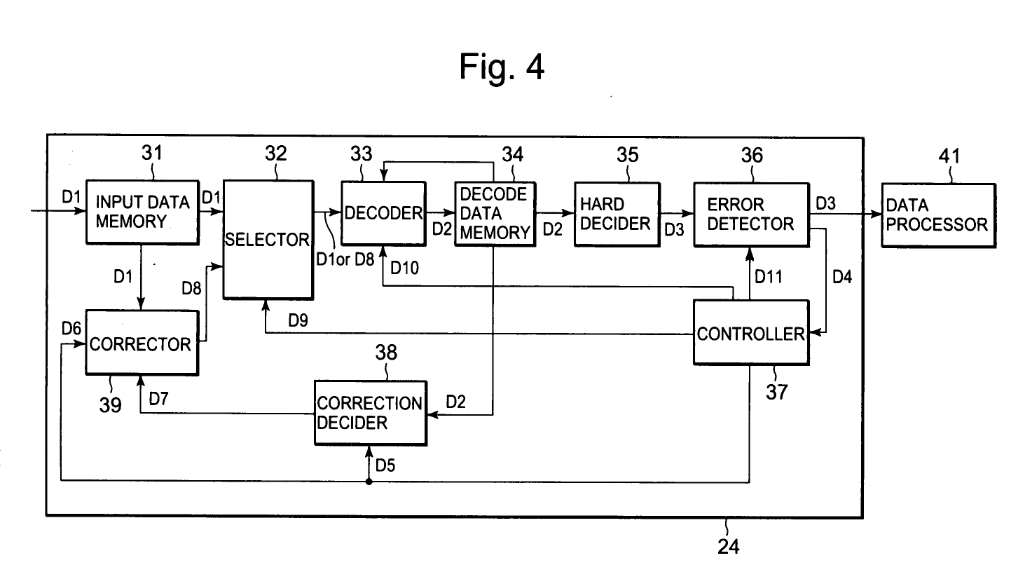

FIG. 4 shows the decoder of this exemplary embodiment (the decoder 23 of FIG. 1 which is hereinafter referred to as a decoding device 24). An input data memory 31 receives from the demodulator 22 and stores the received data of FIG. 2D. For example, the input data memory 31 outputs information and parity 1 of d1, information and parity 1 of d2, information and parity 1 of d3, . . . , and information and parity 1 of d8 of the stored received data for which addresses are designated based on order from a controller 37 to a decoder 33 via a selector 32 (signal line D1). The signal line from the input data memory 31 up to the decoder 33 may be, for example, one capable of outputting multiple bits using a bus or one capable of outputting signals serially. Note that, at this point, the selector selects a signal from the input data memory as a signal to be outputted based on the order from the controller 37. Hereinafter, data ranging from d1 to d8 of FIG. 2 is data corresponding to a processing unit for decoding, e.g., 1 packet.

After acquiring the information and the parity 1 of each of d1 to d8 of FIG. 2D, the decoder 33 performs the turbo decoding on the acquired data. As a result of performing the turbo decoding, the decoder 33 calculates the log-likelihood ratio LLR corresponding to the information and the parity 1 of each of d1 to d8. For example, in FIG. 2E, the decoder 33 calculates a log-likelihood ratio −110 for the information and a log-likelihood ratio 54 for the parity 1 of d1, and calculates a log-likelihood ratio 105 for the information and a log-likelihood ratio −42 for the parity 1 of d2. Further, in a same manner, the decoder 33 calculates the log-likelihood ratios for the information and parities 1 of d3 to d 8. The decoder 33 sequentially outputs and writes the calculated log-likelihood ratios to a decoded data memory 34 (signal line D2).

A log-likelihood ratio is a value relating to probability representing whether a coded bit corresponding to the value is likely 0 or 1. The log-likelihood ratio is expressed by, for example, 8 bits in actual practice. In this case, the log-likelihood ratio takes a value from −128 to 127 in integral. In turbo decoding, processing called a “hard decision” is performed by using the value of the log-likelihood ratio. For example, when the log-likelihood ratio is a value from −128 to 127, the hard decision is processing of deciding that the bit corresponding to the log-likelihood ratio is 0 when a value of the log-likelihood ratio is greater than 0, and that the bit corresponding to the log-likelihood ratio is 1 when the value of the log-likelihood ratio is smaller than 0. Since whether the corresponding number bit of the log-likelihood ratio is 0 or 1 is decided based on whether the log-likelihood ratio is greater or smaller than 0 in the hard decision, the probability of the bit corresponding to the log-likelihood ratio being 0 increases as the value of the log-likelihood ratio becomes closer to 127. The probability of the bit corresponding to the log-likelihood ratio being 1 increases as the value of the log-likelihood ratio becomes closer to −128. In other words, whether a bit corresponding to a log-likelihood ratio having a large absolute value is 0 or 1 is decided with high reliability. For example, if a log-likelihood ratio has an absolute value of 100 or greater and when a bit corresponding to the log-likelihood ratio is decided as “1” or “0,” then the possibility that the decision result is correct is high. If the absolute value of the log-likelihood ratio is 30 to 100, then the reliability of the decision on whether the bit corresponding to the log-likelihood ratio is 0 or 1 is medium degree. If the absolute value of the log-likelihood ratio is less than 30, the reliability of the decision on whether the bits corresponding to the log-likelihood ratio is 0 or 1 is low. In this case, even if whether the bit corresponding to the log-likelihood ratio is 0 or 1 is decided based on the positivity or negativity and the absolute value of the log-likelihood ratio, there is still a possibility that the decision result has error.

The description on the operation of the decoding device 24 will continue. In response to the controller 37 ordering the address for the decoded data, the decoded data memory 34 outputs the log-likelihood ratio corresponding to the information of each of d1 to d8 shown in FIG. 2E to a hard decider 35. The hard decider 35 performs the above-mentioned hard decision on each log-likelihood ratio acquired from the decoded data memory 34. As a result, the hard decider 35 obtains the decoded data of the information of each of d1 to d8 among the decoded data shown in FIG. 3A. The hard decider 35 outputs the obtained decoded data to an error detector 36 (signal line D3).

The error detector 36 decides whether the information bits (FIG. 2A) transmitted by the transmission side has been recovered without error in the decoded data received from the hard decider 35, i.e., the decoded data for the information of each of d1 to d8 shown in FIG. 3A. Specifically, a cyclic redundancy check (CRC) is added to the information bits of FIG. 2A, and the error detector 36 decides whether the decoded data received from the hard decider 35 is correct based on the CRC. In the example shown in FIG. 3A, the information differs between each of d5 and d6 of FIG. 2A and between each of the d5 and d6 of FIG. 3A. In other words, in this example, the error detector 36 judges that the decoded data received from the hard decider 35 has error, and outputs the judgment to the controller 37 (signal line D4 for which 1 bit suffices). Note that, when the error detector 36 judges that the decoded data received from the hard decider 35 is correct, the decoded data is outputted to a data processor 41. The data processor 41 is a block that configures a system including a CPU and a bus and performs predetermined processing on inputted data.

Upon receiving a signal showing that the decoded data outputted by the hard decider 35 has error from the error detector 36, the controller 37 outputs a signal instructing the decoder 33 to perform the decoding again (signal line D10). In other words, the above-mentioned decoding is a first decoding, and a decoding described below is a second decoding. The turbo decoding is a technique that can enhance the accuracy of decoding by repeatedly performing the decoding.

In response to the instruction from the controller 37, the decoder 33 reads and acquires the information and a parity “2” of each of d1 to d8 of the received data shown in FIG. 2D from the input data memory 31. The first decoding differs in that the information and the parities “1” of d1 to d8 have been used. Further, the decoder 33 reads and acquires the log-likelihood ratio for the information of each of d1 to d8 shown in FIG. 2E from the decoded data memory 34 among data written in the decoded data memory 34 in the first decoding. The signal read from the decoded data memory 34 to the decoder 33 is called “extrinsic information” in the field of turbo decoding.

The decoder 33 performs the second turbo decoding using the information and the parity 2 of each of d1 to d8 relating to the received data of FIG. 2D and the log-likelihood ratios (see FIG. 2E) for the information of d1 to d8 read from the decoded data memory 34. As a result of performing the turbo decoding, the decoder 33 calculates the log-likelihood ratio for the information and the parity 2 of each of d1 to d8, and sequentially writes the calculated log-likelihood ratio in the decoded data memory 34. Note that the log-likelihood ratio for the information of each of d1 to d8 calculated in the first decoding is overwritten with the log-likelihood ratio for the information of each of d1 to d8 calculated in the second decoding. Note that, among the log-likelihood ratios calculated by the decoder 33 in the second turbo decoding, those relating to d1 to d8 differ from those shown in FIG. 2E. However, the log-likelihood ratio relating to the parity 2 for each of d1 to d8 is that shown in FIG. 2(e). The log-likelihood ratio for the parity 2 is calculated for the first time in the second turbo decoding, and therefore is also shown in FIG. 2E.

Next, the hard decider 35 reads and acquires the log-likelihood ratio for the information of d1 to d8 in the second decoding from the decoded data memory 34. The hard decision is made in a same manner to the first decoding, and the resulting decoded data is outputted to the error detector 36. Among the decoded result, the parities 2 of d1 to d8 are shown in FIG. 3A. However, the decoded data for the information bits of d1 to d8 differs from that shown in FIG. 3A. This is because the hard decision result for the information bits of d1 to d8 of FIG. 3A is the hard decision result in the first decoding.

The error detector 36 decides whether the decoded data from the hard decider 35 is correct in a same manner to the first decoding. Here, assume that the second decoded results have error in the obtained decoded data. In this case, the error detector 36 transmits the error in the decoded data to the controller 37 via the signal line D4. Upon receiving the result, the controller 37 instructs the decoder 33 again to perform the decoding. In other words, it is the third decoding.

In the third decoding, the decoder 33 reads the information and the parity 1 of each of d1 to d8 of the received data shown in FIG. 2D from the input data memory 31. In this regard, it is similar to the first decoding. However, it differs in that the decoder 33 reads and acquires the log-likelihood ratios for the information of d1 to d8 written in the decoded data memory 34 in the second decoding from the decoded data memory 34, and uses the log-likelihood ratio for the third decoding. The first decoding and third decoding differ in terms of the log-likelihood ratios read from the decoded data memory. Thus, since input values used in the first and the third decoding differ, the decoded results may also differ in the first and the third decoding. The processing thereafter is same to the first decoding. The decoder 33 writes the log-likelihood ratios for the information and the parities 1 of d1 to d8 to the decoded data memory. The log-likelihood ratios for the information and the parities 1 of d1 to d8 written in the first decoding are overwritten with the log-likelihood ratios of the information and the parities 1 of d1 to d8 calculated in the third decoding. The hard decider 35 reads the log-likelihood ratios of the information (corresponding to the third decoding) of d1 to d8 from the decoded data memory, and makes the hard decisions therefor. The hard decider 35 outputs the obtained decoded data to the error detector 36. The error detector 36 decides whether or not the decoded data has error in a same manner.

When the third decoding has also error, the decoder 33 performs a fourth decoding upon receiving an instruction from the controller 37. At this time, the decoder 33 reads the information and parities 2 of d1 to d8 from the input data memory 31 for use in the decoding in a same manner to the second decoding. However, the decoder 33 reads the log-likelihood ratio for the information of each of d1 to d8 written in the decoded data memory in the third decoding for use in the decoding. In this regard, it differs from the second decoding. Since input values used for the decoding differ from all of those in the first, second, and third decoding, a result different from the first to third decoded results may be obtained. The processing thereafter is similar to the first to third decoding.

Here, assume that an error of the fourth decoding is transmitted to the controller 37 from the error detector 36. The controller 37 recognizes that a correct decoded result has not been able to be obtained after four times of repeated decoding, and instructs a correction decider 38 and a corrector 39 to correct the received data (FIG. 2D) stored in the input data memory (signal lines D5 and D6).

When an instruction to correct the received data stored in the input data memory 31 is received from the controller 37 via the signal line D5, the correction decider 38 reads the information, the parities 1, and the parities 2 of d1 to d8 from the decoded data memory. Hereinafter, for an easier illustration, the data read from the decoded data memory 34 by the correction decider 38 is deemed to be that shown in FIG. 2E. In actual practice, the data stored in the decoded data memory 34 at the time when the repeated decoding is finished differs from that of FIG. 2E since the repeated decoding has been performed four times by the decoder 33. As described above, for example, the log-likelihood ratio for the information of each of d1 to d8 of FIG. 2E is written in the decoded data memory 34 by the decoder 33 when the decoder 33 has performed the first turbo decoding. The log-likelihood ratio relating to the parity 1 of each of d1 to d8 of FIG. 2E is written in the decoded data memory when the decoder 33 has performed the first turbo decoding in a same manner. The log-likelihood ratio for the parity 2 of each of d1 to d8 of FIG. 2E is written in the decoded data memory when the decoder 33 has performed the second turbo decoding. Thus, at the point when the decoder 33 has repeated the turbo decoding for four times, the log-likelihood ratios stored in the decoded data memory 34 do not coincide with those of FIG. 2E. However, in the description below, for an easier illustration using actual values as examples, the log-likelihood ratios shown in FIG. 2E are deemed as data held by the decoded data memory at the time when the fourth turbo decoding is finished.

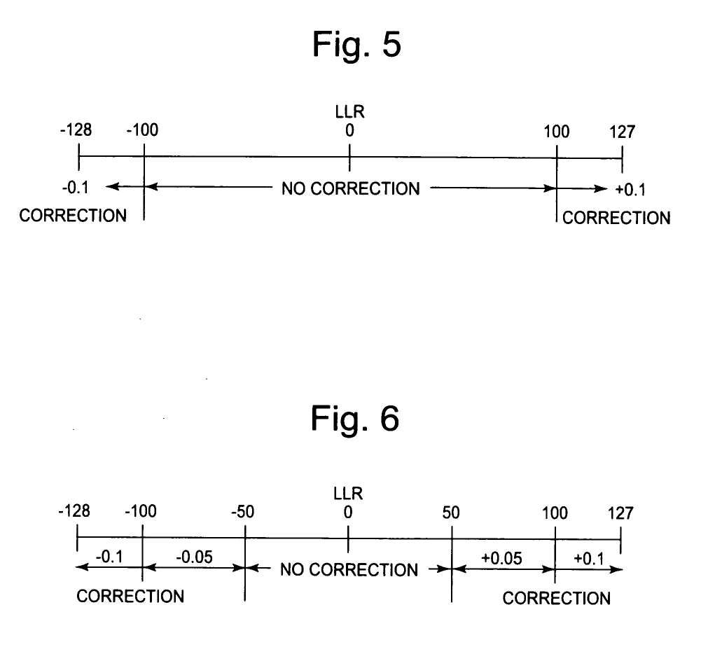

The correction decider 38, as described below, makes decisions on the respective log-likelihood ratios read from the decoded data memory 34. Note that the processing contents of the correction decider 38 shown below are specific examples, and the scope of claims should not be limited to the description of this exemplary embodiment. When the sign of a log-likelihood ratio is positive and the absolute value of the log-likelihood ratio is equal to or greater than 100, the correction decider 38 determines to increase the value of the received data corresponding to the log-likelihood ratio by 0.1. For example, the log-likelihood ratio for the information of d3 of FIG. 2E is 100. Thus, it is determined that the information 0.73 of d3 that is the received data of FIG. 2D corresponding to the log-likelihood ratio should be increased to 0.83. The specific calculation is performed by the corrector 39 described later, but the result of the calculation is shown by the fact that the information of d3 among the correction data of FIG. 3B is −0.83. Next, when the sign of a log-likelihood ratio is negative and the absolute value of the log-likelihood ratio is equal to or greater than 100, the correction decider 38 determines to decrease the value of the received data corresponding to the log-likelihood ratio by 0.1. For example, the log-likelihood ratio for the information of d1 of FIG. 2E is −110. Thus, it is determined that the information −0.80 of d1 that is the received data of FIG. 2D corresponding to the log-likelihood ratio should be −0.90. The specific calculation is performed by the corrector 39 described later, but the result of the calculation is shown by the fact that the information of d1 among the correction data of FIG. 3B is −0.90. On the other hand, for the received data corresponding to each of the log-likelihood ratio for which the absolute value is less than 100, the correction decider 38 determines not to perform the increase or decrease of the value. The determination content of the correction decider 38 is shown in FIG. 5. The correction decider 38 determines how to correct each piece of the received data stored in the input data memory 31 based on the log-likelihood ratio obtained as a result of repeatedly performing the turbo decoding.

Note that the description above is a specific example, and the absolute value of the log-likelihood ratio used by the correction decider 38 may be not 100, for example. The specific value by which a value of the received data is increased or decreased by the correction decider 38 may be not 0.1. A high absolute value of the log-likelihood ratio indicates that the result of the hard decision is reliable. Thus, a threshold value of the log-likelihood ratio by which the result of the hard decision is estimated to be correct may be set to a value according to the situation. The correction decider 38 evaluates the absolute value of the log-likelihood ratio, and finds the log-likelihood ratio by which a correct hard decision is estimated to be performed. The correction decider determines that the values of the received data corresponding to the log-likelihood ratios should be corrected.

How to correct the value of the received data is determined by a policy described below. For example, among the log-likelihood ratios of FIG. 2E, the log-likelihood ratio for the information of d1 is −110. If the threshold value of the absolute value of the log-likelihood ratio for which the correct hard decision is estimated to be performed is 100, then the log-likelihood ratio of the information of d1 is a log-likelihood ratio for which the correct hard decision can be estimated to be performed. The result of the hard decision on the log-likelihood ratio −110 becomes 1, and this hard decision result is estimated to be correct. The received data corresponding to the log-likelihood ratio −110 of the information of d1 is −0.80 according to FIG. 2D. On the transmitter side, the code data of FIG. 2B is subjected to BPSK modulation. In the BPSK modulation, data for which the value of the bit is 1 as code data is converted to −1.00, and data for which the value of the bit is 0 is converted to 1.00. Since the corresponding hard decision result for the received data −0.80 for the information of d1 of FIG. 2D is 1 and the result of the hard decision corresponding to −0.80 is further estimated to be correct, it is conceivable that −0.80 has been originally −1.00 without the influence of noise. Thus, the correction decider 38 determines to correct the value of −0.80 to be closer to −1.00. In performing the correction, the specific value added to −0.80 has been −0.1 in the example described above.

In other words, when the result of the hard decision made for a log-likelihood ratio can be estimated to be correct, the correction decider 38 determines to correct the value of the received data corresponding to the log-likelihood ratio to be closer to a likely value that would have been indicated without the influence of noise. The specific value used in the addition or subtraction for the correction may be determined according to the situation.

The correction decider 38 transmits what correction is to be performed to which part among the received data of FIG. 2D to the corrector 39 via a signal line D7. Meanwhile, the controller 37 transmits to the corrector 39 via a signal line D6 what value to be added to or subtracted from the part of the received data to be corrected.

The corrector 39 reads the received data of FIG. 2D from the input data memory 31. The corrector 39 performs the correction on the part of the received data instructed from the correction decider 38 by adding or subtracting the value acquired from the controller 37. The corrector 39 internally includes a memory in which the corrected received data is stored. Specifically, the data of FIG. 3B is stored.

After the corrector 39 has stored the correction data, the controller 37 instructs the decoder 33 to perform the decoding again. The controller 37 sends an instruction to the selector 32 so that the data from the corrector 37 is transmitted to the decoder 33. The decoder 33 first acquires the information and the parity 1 for each of d1 to d8 among the received data after correction, i.e., the correction data shown in FIG. 3B, from the corrector 39. Then, the first turbo decoding is performed. The operations of the decoder 33, the decoded data memory 34, the hard decider 35, the error detector 36, and the controller 37 in the turbo decoding are similar to those described above. When the result of the first decoding using the received data after correction has error, the decoder 33 acquires the information and the parity 2 for each of d1 to d8 among the correction data of FIG. 3B from the corrector 39 in response to the instruction from the controller 37. Upon acquiring the log-likelihood ratios for the information of d1 to d8 written in the first decoding from the decoded data memory 34 as the extrinsic information, the second turbo decoding is performed. The third decoding and the fourth decoding are similar to those described above. Note that they differ in that the decoder 33 acquires the received data after correction from the corrector 39.

When a correct decoded result cannot be obtained even by performing the turbo decoding using the data after correction shown in FIG. 3B, the controller 37 instructs the correction decider 38 and the corrector 39 to further correct the received data after correction (FIG. 3B) stored in the corrector 39.

The correction decider 38 and the corrector 39 that have received the instruction correct the received data after correction stored in the corrector 39 in similar steps to those described above. The further corrected received data is used again in turbo decoding.

The correction performed by the correction decider 38 and the corrector 39 may be repeated until a correct decoded result is obtained or may be performed for a predetermined number of times. In this exemplary embodiment, the log-likelihood ratio is used as a criterion in determining whether the correction is to be performed for each part of the received data by the correction decider. This is for the decoder 33 to perform the turbo decoding. There is, for example, the Viterbi decoding other than the turbo decoding as a decoding method of an error correcting code. In the Viterbi decoding, how a surviving path on a trellis diagram has been selected is stored in a path memory as a result of the decoding, and a parameter such as a path metric or a path metric difference may be additionally stored so that the parameters are used to correct the received data used in the decoding.

In this exemplary embodiment, it suffices that the correction decider 38 includes a comparator that compares the respective log-likelihood ratios read from the decoded data memory 34 and the threshold value of the absolute value of the log-likelihood ratio by which the result of the hard decision can be estimated to be correct (for example, a configuration suffices in which the threshold value of the log-likelihood ratio is instructed by the controller 37 to the corrector 39). Also, it suffices that the corrector 39 includes an adder and a memory that stores 1 packet of the received data.

In this exemplary embodiment, the input data memory 31 continues to keep the received data (FIG. 2D) regardless of the presence or absence of the correction of the received data. Thus, in the case where the decoder 33 fails to obtain a correct decoded result by performing the decoding even after the correction decider 38 and the corrector 39 repeatedly perform the correction of the received data, the decoder 33 can perform the decoding again using the received data stored in the input data memory 31, after a change of the threshold value of the log-likelihood ratio used to estimate that the result of the hard decision is correct, or after a change of the value that the corrector 39 adds to or subtracts from the part corresponding to the received data in order to correct the received data. Alternatively, the correction data stored in the corrector 39 may be corrected again to perform decoding using the threshold value of the absolute value of the log-likelihood ratio after the change and/or the value to be used for correction after the change.

In this exemplary embodiment, the correction decider 38 and the corrector 39 have performed the correction of the received data when the decoder 33 cannot obtain a correct decoded result by repeatedly performing the decoding even four times. However, the number of times of the repeated decoding is not limited to four times. Note that, when the repeated number of times is small, the reliability of the log-likelihood ratio stored in the decoded data memory may be low and therefore requires attention. The log-likelihood ratio obtained as a result of the turbo decoding converges and stabilizes by repeating the turbo decoding. Thus, in a state where the repeated number of times of the turbo decoding is small, the value of the log-likelihood ratio stored in the decoded data memory has not converged. Therefore, the correction decider 38 and the corrector 39 should perform the correction of the received data after the turbo decoding has been repeated to some extent. This is because, if the correction decider 38 determines which part of the received data the correction is to be performed based on the log-likelihood ratio that has not converged, then, the possibility that the determination is appropriate for obtaining a correct decoded result becomes low.

FIG. 6 shows a modified example of the operations of the correction decider 38 and the corrector 39 described above. In the exemplary embodiment described above, there has been one threshold value of the absolute value of the log-likelihood ratio for which the result of the hard decision is estimated to be reliable. However, in FIG. 6, two threshold values of the absolute value are set. Specifically, they are 100 and 50. Thus, the correction decider 38 determines that the correction should be performed for the received data corresponding to the log-likelihood ratio whose absolute value exceeds 50 among the log-likelihood ratios read from the decoded data memory 34. However, since there are two types of the value to be added to the received data for which the corrector 39 is to perform the correction, the correction decider 38 designates, to the corrector 39, the part of the received data to be corrected and instructs what value needs to be added. The corrector 39 receives the two types of values to be added from the controller 37. Specifically, the correction decider 38 estimates that the result of the hard decision is correct without fail when the absolute value of the log-likelihood ratio exceeds 100, and instructs the corrector 39 that a correction value is 0.1. On the other hand, when the value of the log-likelihood ratio is less than 100 and is equal to or greater than 50, the correction decider 38 estimates that the result of the hard decision is seemingly probable, and instructs the corrector 39 that the correction value is 0.05. As for the received data corresponding to the absolute value of the log-likelihood ratio which is less than 100 and is equal to or greater than 50, an inappropriate correction that adversely affects the result of the decoding is prevented by performing the correction using 0.05 which is smaller than 0.1.

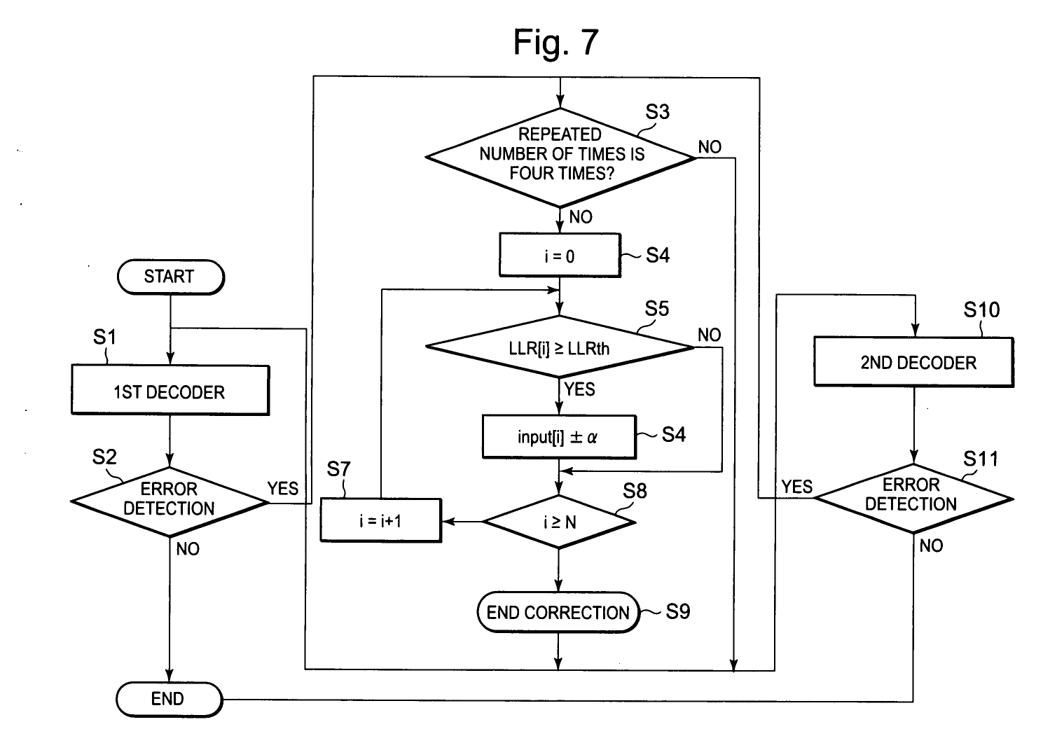

FIG. 7 is a flowchart showing a correction method according to the exemplary embodiment. Steps S3 to S9 are steps of performing correction processing according to this exemplary embodiment, and the correction is performed on bits for which the reliability has exceeded the threshold value.

The decoder 33 includes a first decoder and a second decoder, and these decoders alternately perform the decoding by alternately performing decode processing. First, the first decoder performs decoding (step S1), and the error detector 36 performs error detection on the result (step S2). If there is no error, then the processing ends. On the other hand, when an error is detected, decoding is repeatedly performed by the first decoder and the second decoder until the repeated number of times of the decoding reaches a predetermined number of times, which is four times in this example. If the repeated number of times is less than four times, then it proceeds to step S10 where the second decoder performs the decode processing. Then, the error detector 36 performs the error detection (step S11). In a same manner to that described above, the processing ends if no error is detected.

On the other hand, when an error is detected, it again proceeds to step S3. Assume that the repeated number of times has been four times. In this case, it proceeds to step S4 to perform the correction processing. First, as to a first bit (i=0) (step S4) of input data, whether or not the absolute value of LLR[i] is equal to or greater than a threshold value LLRth is judged. As described above, the threshold value is equal to or greater than 100 in absolute value. If the LLR is equal to or greater than the threshold value LLRth, then a predetermined value a is added to input data input[i] direction to the hard decision direction of LLR[i]. In other words, if the input data is 0.8 and the hard decision result of the LLR is 0, then it becomes 0.8+α, and if the hard decision result of the LLR is 1, it becomes 0.8−α (α>0) (step S4). If it is smaller than the threshold value, then the next input data is checked. When the threshold value judgement of the LLR is finished for all pieces of data N corresponding to 1 packet, the correction processing is ended (steps S7 to S9).

This will be specifically described. In FIG. 2D, data d7 is received with such a superimposed noise that the sign is inverted. Therefore, the log-likelihood ratios of d5 and d6 are inclined toward incorrect directions as a result of decoding, causing an error in the decoded data. On the other hand, an error of d7 is corrected, and the same result 1 as the transmission data is obtained (FIG. 3A). In this example, input data for which the absolute value of decoded data reliability is equal to or greater than 100 is modified. Accordingly, the input data of d1, d2, d3, d7, and d8 is subject to correction in terms of only the information bits since the decoded data of the data d1 is 1, a correction of −0.1 is performed as described above. Thus, −0.80 becomes −0.90. Since the decoded data of the data d3 is 0, a correction of +0.1 is performed, so that 0.73 becomes 0.83. Meanwhile, since the decoded data of the data d7 is 1, 0.31 becomes 0.21 (FIG. 3B). The input data of d5 and d6 for which incorrect decoded data is obtained is not corrected, but the errors of d5 and d6 are corrected in the next decoding because surrounding data is corrected and becomes closer to the data at the time of transmission (FIGS. 3C and 3D).

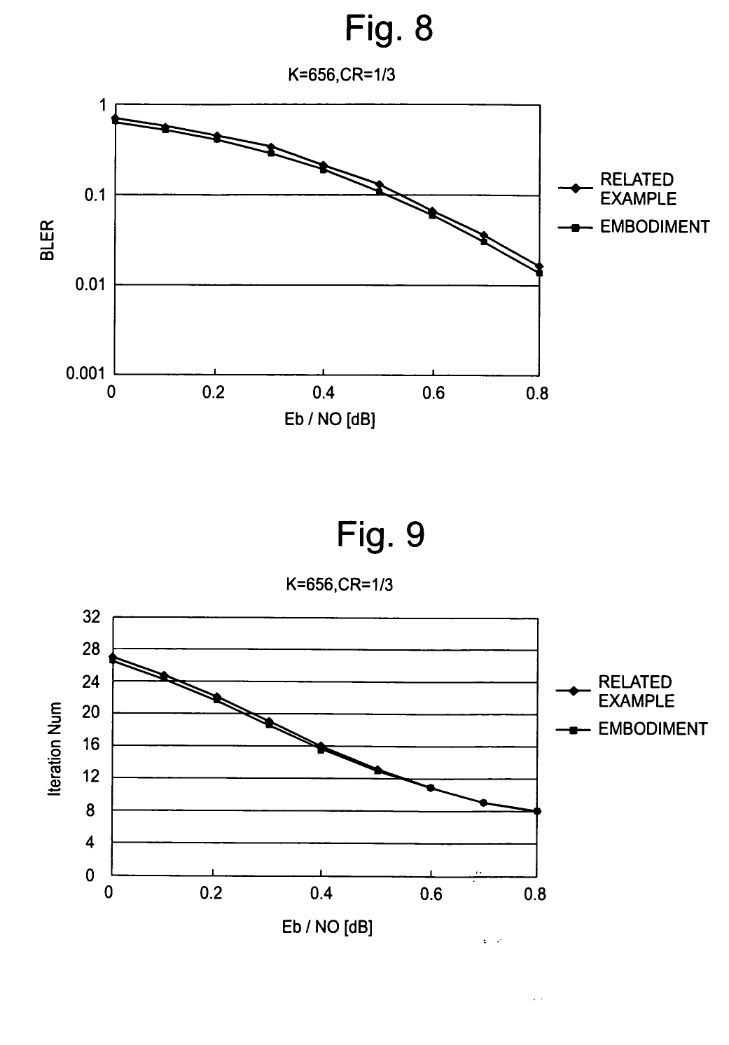

FIG. 8 is a view showing the effect of the exemplary embodiment of the present invention, and is a graph diagram showing the error correction capability. As shown in FIG. 8, performing the decoding method according to this exemplary embodiment improves the error correction capability. FIG. 8 shows an improvement effect of the correction capability in turbo decoding regarding a 656 bit information size and a 1/3 coding rate. As compared to the performance of a general decoding circuit (related art example), it can be seen that the decoding circuit according to this exemplary embodiment exhibits higher performance.

FIG. 9 is a view showing another effect of the exemplary embodiment of the present invention, and is a graph diagram showing a reduction effect in the repeated number of times of decoding for the error correction. As shown in FIG. 9, the number of times of the repeated decoding is reduced by the improvement in the correction capability.

In this exemplary embodiment, only the input data whose LLR is higher than the predetermined threshold value and can be considered reliable is subject to correction and corrected. Accordingly, the probability of a wrong correction is low. The error correction capability is improved by the correction processing of this exemplary embodiment. As a result, the number of times of the repeated decoding is reduced to achieve an increase in speed of the processing.

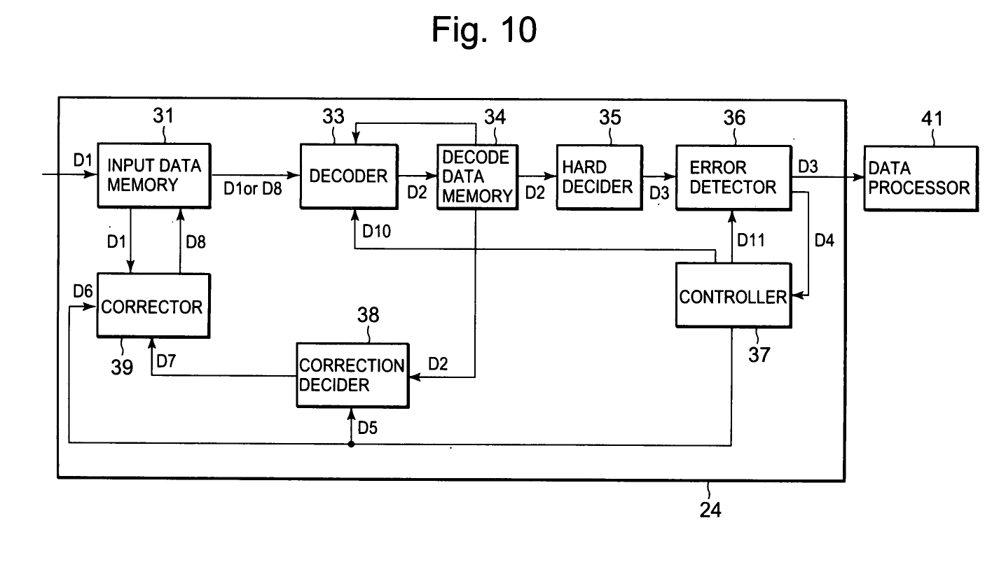

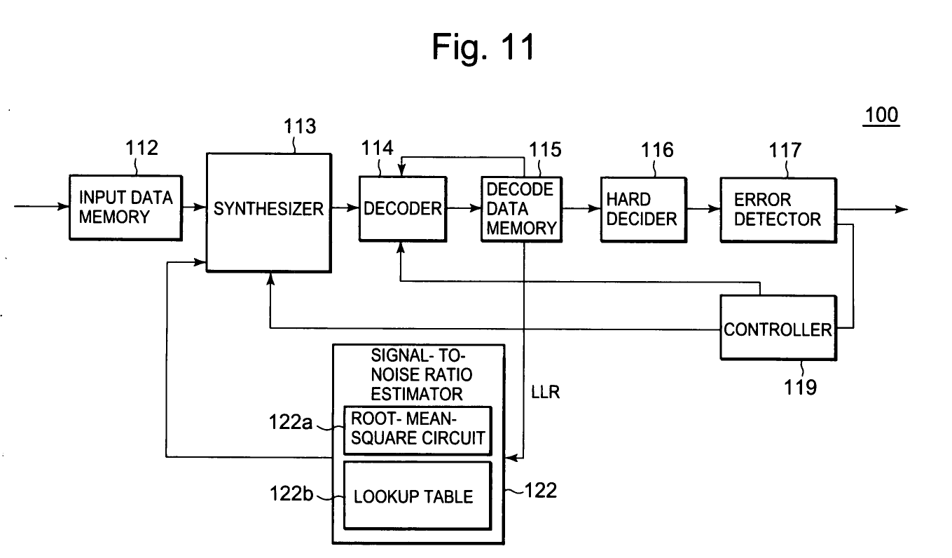

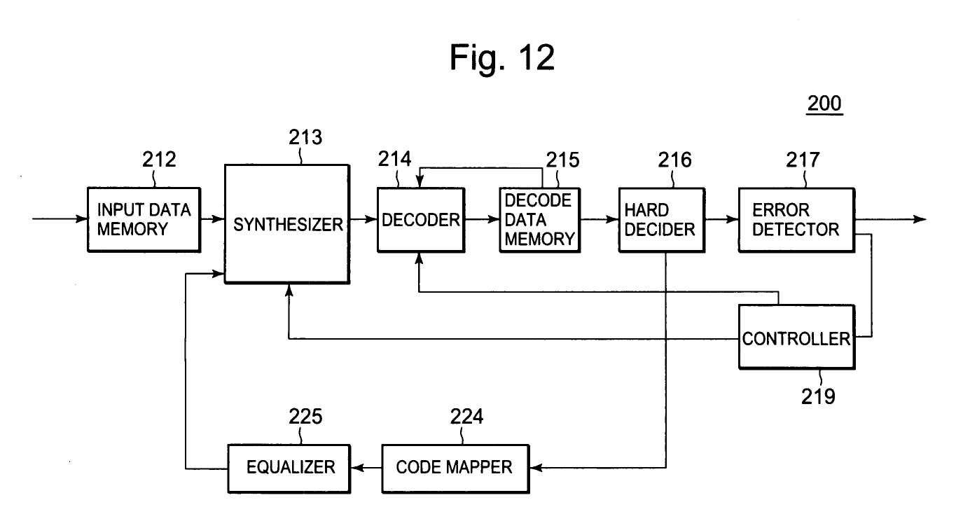

FIG. 10 is a view showing a decoding device according to second exemplary embodiment of the present invention. Note that the overall configuration shown in FIG. 1 is similar to that of the first exemplary embodiment. The same components as those of the first exemplary embodiment shown in FIG. 4 are denoted by the same reference numerals and detailed descriptions thereof are omitted.

As shown in FIG. 10, this exemplary embodiment has a configuration in which the corrector 39 writes back data in the input data memory 31. Therefore, the selector which has been necessary in the first exemplary embodiment is unnecessary. Since the corrector 39 writes back the data after correction in the input data memory, the memory which has been necessary for the corrector 39 becomes unnecessary, and the circuit size can be reduced.

Next, other exemplary embodiments will be described. It has been described that the decoded data memory 34 calculates and holds the LLR of not only the information bits but also the parity bits, but only the LLR of the information bits may be held. In other words, among the input data, it is possible that only the information bits are subject to correction. In this case, since the decoded data memory does not need to hold the LLR of the parity bits, the memory capacity can be reduced, and consequently the circuit size can be reduced.

Further, instead of saving the LLR of the parity bits, a correction decision result of the parity bits may be saved. The LLR of the information bits is necessary for use as the extrinsic information of the next decoding, but the LLR of the parity is used only in a correction decision and thus is unnecessary. Accordingly, when there is one LLR threshold value, the information of each bit can be reduced to 1 bit that shows whether or not to perform the correction, as compared to when the LLR (for example 8 bits) is saved. In this case, it suffices that the correction decider 38 receives the LLR from the decoder 33 and writes only the correction decision result in the decoded data memory 34, or the correction decider 38 itself holds the correction decision result.

The threshold value on whether or not it is subject to correction can be a value determined in advance, but it is also possible to obtain the threshold value based on the distribution/mean amplitude of the input data or the distribution/mean amplitude of the reliability. Since the reliability distribution changes every time the decoding is repeated, the threshold value may be determined separately according to the repeated number of times.

Note that the present invention is not limited to the exemplary embodiments described above, and it is a matter of course that various changes are possible without departing from the gist of the present invention. For example, in the exemplary embodiment described above, a hardware configuration has been described. However, it is not limited thereto, and it is also possible to achieve arbitrary processing by causing a CPU (Central Processing Unit) to execute a computer program. In this case, the computer program can possibly be provided by being recorded on a recording medium, or can possibly be provided by transmission via the Internet or other transmission media.

In the exemplary embodiment described above, an example in which the present invention is applied to turbo decoding has been described. However, the present invention can be applied to any decoding capable of a soft output such as the convolutional code of the Viterbi decoding or the like that can obtain a soft output or an LDPC (low-density parity-check code), since a soft output, e.g., the log-likelihood ratio (LLR), can be obtained for every bit of the received data.

Further, it is noted that Applicant's intent is to encompass equivalents of all claim elements, even if amended later during prosecution.

What is claimed is:

1. A decoding method of performing a turbo decoding on a data that includes a first value before the data have been transmitted and that includes a second value after the data is received, the second value being changed from the first value due to an influence of a transmission path, the decoding method comprising:
performing the turbo decoding on the data to obtain a log-likelihood ratio for the second value;
converting the second value to a third value that is obtained by correcting the second value to become closer to the first value when a decoded result from the turbo decoding on the data includes an error, and when an absolute value of the log-likelihood ratio is equal to or greater than a predetermined threshold value; and
performing the turbo decoding on the data including the third value to obtain a decoded result of the data.

2. The decoding method according to claim 1, wherein the log-likelihood ratio comprises a first log-likelihood ratio, the method further comprising:
performing the turbo decoding on the data including the third value to obtain a second log-likelihood ratio for the third value;
converting the third value to a fourth value that is obtained by correcting the third value to become closer to the first value when a decoded result obtained from the turbo decoding on the data including the third value, includes an error and the second log-likelihood ratio is equal to or greater than the predetermined threshold value; and
performing the turbo decoding on the data including the fourth value.

3. The decoding method according to claim 2, wherein the third value is converted to the fourth value by correcting by an amount different from an amount by which the second value is corrected, when the decoded result obtained from the turbo decoding on the data including the third value indicates the error.

4. The decoding method according to claim 2, wherein a value of the predetermined threshold value is changed when the decoded result obtained from the turbo decoding on the data including the third value indicates the error.

5. The decoding method according to claim 1, wherein
the second value is changed by a first correction value and thereby is converted to the third value when the absolute value of the log-likelihood ratio is equal to or greater than a first threshold value, and
the second value is changed by a second correction value which is smaller than the absolute value of the first correction value and thereby is converted to the third value when the absolute value of the log-likelihood ratio is less than the first threshold value and is equal to or greater than a second threshold value which is lower than the first threshold value.

6. The decoding method according to claim 1, wherein the log-likelihood ratio comprises a log-likelihood ratio obtained as a result of performing the turbo decoding on the data a plurality of times.

7. A decoding device, comprising:
a decoder that performs turbo decoding on data that includes a first value before transmission, and that includes a second value after reception, the second value being changed from the first value due to the influence of a transmission path, and thereby obtaining a log-likelihood ratio for the second value;
a correction decider that issues an instruction to correct the second value when a decoded result from the turbo decoding indicates an error and when an absolute value of the log-likelihood ratio is equal to or greater than a predetermined threshold value; and
a corrector that converts the second value to a third value that is obtained by correcting the second value to become closer to the first value, wherein
the decoder performs the turbo decoding again on the data including the third value.

8. A decoding method, comprising:
receiving, at an input data memory, an information data and a first parity and a second parity, the first and second parities being related to the information data;
decoding, by a decoder, the information data and the first parity to obtain a first log-likelihood ratio for the input data and a second log-likelihood ratio for the first parity;
storing the first log-likelihood ratio and the second log-likelihood ratio into a decoded data memory;
producing, by a hard decider, a first decoded data based on the first log-likelihood ratio, and a second decoded data based on the second log-likelihood ratio;
detecting, by an error detector, whether the first decoded data includes an error, based on a cyclic redundancy check, in order to produce a first error signal when detecting that the first decoded data includes the first error;
by the decoder, obtaining the information data, the second parity and the first log-likelihood ratio from the decoded data memory to obtain a third log-likelihood ratio for the information data and a fourth log-likelihood ratio for the second parity;
storing the third and fourth log-likelihood ratios into the decoded data memory;
producing, by the hard decider, a third decoded data based on the third log-likelihood ratio, and a fourth decoded data based on the fourth log-likelihood ratio;
detecting whether the third decoded data includes a second error, based on the cyclic redundancy check, in order to produce the error signal when the error detector detects that the third decoded data includes the second error;
by the decoder, obtaining the information data, the first parity, and the third log-likelihood ratio from the decoded data memory to produce a fifth log-likelihood ratio for the information data and a sixth log-likelihood ratio for the first parity;
storing the fifth and sixth log-likelihood ratios into the decoded data memory;
producing, by the hard decider, a fifth decoded data based on the fifth log-likelihood ratio, and a sixth decoded data based on the fifth log-likelihood ratio;
detecting whether the fifth decoded data includes a third error, based on the cyclic redundancy check, in order to produce the error signal when the error detector detects that the fifth decoded data includes the third error;
in response to the error signal generated when the error detector detects that the fifth decoded data includes the third error, obtaining the information data, the first parity, the second parity, the fourth log-likelihood ratio, the fifth log-likelihood ratio, and the sixth log-likelihood ratio, to correct the information data, the first parity, and the second parity, respectively when each value of the fourth log-likelihood ratio, the fifth log-likelihood ratio, and the sixth log-likelihood ratio exceeds a threshold value;
by the decoder, obtaining a corrected information data and a corrected first parity to produce a seventh log-likelihood ratio for the corrected information data and an eighth log-likelihood ratio for the corrected first parity;
producing, by the hard decider, a seventh decoded data based on the seventh log-likelihood ratio, and an eighth decoded data based on the eight log-likelihood ratio; and
detecting whether the seventh decoded data includes an error, based on the cyclic redundancy check.

9. The decoding method as claimed in claim 8, wherein
when a positive LLR value of the information data, a positive value of the first parity, and a positive LLR value of the second parity exceeds a first threshold value, a first correction value is added to the respective positive values of the information data, the first parity and the second parity.

10. The decoding method as claimed in claim 8, wherein
when a negative LLR value of the information data, a negative LLR value of the first parity, and a negative LLR value of the second parity is lower than a second threshold value, a second correction value is subtracted from the respective positive values of the information data, the first parity and the second parity.
